(19) United States
(12) Patent Application Publication
(10) Pub. No.: US 2024/0170913 A1
(43) Pub. Date: May 23, 2024

(54) SURFACE LIGHT EMITTING ELEMENT WITH HIGH HEAT DISSIPATION AND UNIFORM LIGHT EMISSION

(71) Applicant: HIGH POWER OPTO. INC., Taichung City (TW)

(72) Inventors: Chih-Sung CHANG, TAICHUNG CITY (TW); Wei-Yu YEN, TAICHUNG CITY (TW); Wayne JAN, TAICHUNG CITY (TW); Tau-Jin WU, TAICHUNG CITY (TW)

(21) Appl. No.: 17/990,221

(22) Filed: Nov. 18, 2022

(51) Int. Cl. H01S 5/024; H01S 5/0236; H01S 5/028; H01S 5/183

(52) U.S. Cl. CPC H01S 5/02469; H01S 5/0236; H01S 5/02476; H01S 5/028; H01S 5/18308; H01S 5/18375

(57) ABSTRACT

A surface light emitting element with high heat dissipation and uniform light emission includes a metal reflective layer, a first metal conductive layer, an omnidirectional reflecting current isolation layer, a first-type semiconductor current spreading layer, a light emitting diode layer, a second-type semiconductor current spreading layer and a second metal conductive layer. The metal reflective layer includes at least one surrounding wall structure. The omnidirectional reflecting current isolation layer is arranged on the metal reflective layer and entirely covers the two sides of the at least one surrounding wall structure to form at least one cylindrical channel. The light emitting diode layer is located in the at least one cylindrical channel.

### FIELD OF THE INVENTION

The invention relates to a surface light emitting element, in particular to a surface light emitting element with high heat dissipation and uniform light emission.

### BACKGROUND OF THE INVENTION

A surface light emitting structure is a semiconductor structure emitting light from the top surface, such as Taiwanese Patent No. 1268031 entitled Vertical Cavity Surface Emitting Laser and Preparation Method Therefor and Taiwanese Patent No. 1403050 entitled Vertical Cavity Surface Emitting Laser (VCSEL), VCSEL Array Apparatus, Optical Scanning Device and Image Forming Device.

In order to improve the light emission luminance of the surface light emitting element, as disclosed in U.S. Pat. No. 7,109,527 B2 entitled Semiconductor chip for optoelectronics and method for production thereof and U.S. Pat. No. 7,547,921 B2 entitled Semiconductor chip for optoelectronics, the surface light emitting element has a insulating channel in a valley shape restricting a current to flow through the valley-shaped insulating channel. A light emitting layer is arranged in the insulation channel. The insulation channel restricts the current to pass through the light emitting layer, and oblique surfaces on sides of the insulating channel in a valley shape are reflection surfaces to concentrate reflection. Thus, the illumination brightness may be improved.

However, the current has the characteristic of concentratively passing through a lowest resistance path using structure described in U.S. Pat. No. 7,109,527 B2 and U.S. Pat. No. 7,547,921 B2 as examples, the current concentratively flow through the edge of the insulating channel. This causes the problem of uneven light emission with high brightness in a local region and the problem of an element is burnt or shortens lifespan due to high temperature as a local high temperature is easily generated.

However, in order to improve the heat dissipation effect, referring to FIG. 16 and FIG. 17 in Patent No. U.S. Pat. No. 7,547,921 B2, layers with high thermal conductivity are arranged on the inner sides of the oblique surfaces. However, the metal layer is arranged obliquely for being attached to the oblique surfaces, so that a lower region of the metal layer has a larger area and has a better heat dissipation condition compared with an upper region. Therefore, only the lower region of the metal layer may successfully discharge heat, so that the heat will be concentrated in the upper region of the metal layer, which results in concentrated heat dissipation path and compromised thermally conduction effect.

### SUMMARY OF THE INVENTION

A main objective of the invention is to provide a surface light emitting element with high heat dissipation and uniform light emission, which meets the demands for high uniformity and long lifespan.

The invention provides a surface light emitting element with high heat dissipation and uniform light emission including a thermally-conductive and electricity-conductive substrate, a metal adhesive layer, a metal reflective layer, an omnidirectional reflecting current isolation layer, a first metal conductive layer, a first-type semiconductor current spreading layer, a light emitting diode layer, a second-type semiconductor current spreading layer, a second metal conductive layer, and an anti-reflection layer. The metal adhesive layer is arranged on the thermally-conductive and electricity-conductive substrate. The metal reflective layer is arranged on the metal adhesive layer and includes at least one surrounding wall structure. The at least one surrounding wall structure is vertically arranged and is in a surrounding shape. The omnidirectional reflecting current isolation layer is arranged on the metal reflective layer and entirely covers two faces of the at least one surrounding wall structure to form at least one cylindrical channel. In each of the at least one cylindrical channel, the omnidirectional reflecting current isolation layer is formed with at least one channel opening exposing the metal reflective layer. The first metal conductive layer is arranged on the metal reflective layer and is formed at least one circular platform in each of the at least one channel opening. The first-type semiconductor current spreading layer is arranged on the first metal conductive layer and the omnidirectional reflecting current isolation layer. The first-type semiconductor current spreading layer is located in the at least one cylindrical channel.

The light emitting diode layer is arranged on the first-type semiconductor current spreading layer and is located in the at least one cylindrical channel. The second-type semiconductor current spreading layer is arranged on the light emitting diode layer, fully fills the at least one cylindrical channel and covers the omnidirectional reflecting current isolation layer. The second metal conductive layer is arranged on the second-type semiconductor current spreading layer and is arranged away from the at least one cylindrical channel. The second-type semiconductor current spreading layer is provided with at least one light exit opening aligning to the at least one cylindrical channel. The anti-reflection layer is arranged on the second-type semiconductor current spreading layer and is located in the at least one light exit opening.

On the basis of this, in the invention, the at least one cylindrical channel limits a current to pass through the light emitting diode layer. The omnidirectional reflecting current isolation layer is arranged on the metal reflective layer and forms a total reflection interface. As the omnidirectional reflecting current isolation layer covers the surrounding wall structure, a narrower barrier region with enough space for light diffuse that effectively uniforms light emission is provided. Also, the surrounding wall structure of the metal reflective layer is located on the side of the light emitting diode layer and is vertically arranged. Light emitting area sacrificed to provide the surrounding wall structure is smaller than that of an oblique side wall structure (U.S. Pat. No. 7,547,921 B2), so that, more surrounding wall structures may be arranged for assisting heat dissipation while obtaining the same total light emitting surface. Therefore, heat transfer paths of the light emitting diode layer and the surrounding wall structure are dispersed. The heat dissipation efficiency is improved due to avoiding concentrated heat, and the heat produced by the light emitting diode layer is rapidly conducted away. Therefore, compared with the conventional surface light emitting element, the invention provides a light emitting structure with high heat dissipation and uniform light emission.

### BRIEF DESCRIPTION OF THE DRAWINGS

FIG. 1 is a sectional diagram of a surface light emitting element of the invention.

FIG. 2 is a schematic structural diagram of forming a cylindrical channel by an omnidirectional reflecting current isolation layer of the invention.

FIG. 3 is a schematic diagram of a light emitting path of the surface light emitting element of the invention.

FIG. 4 is a schematic diagram of a thermal conduction path of the surface light emitting element of the invention.

### DETAILED DESCRIPTION OF THE PREFERRED EMBODIMENTS

The features, the objectives and the efficacies of the invention and a preferred embodiment are listed for description with the drawings together as follows:

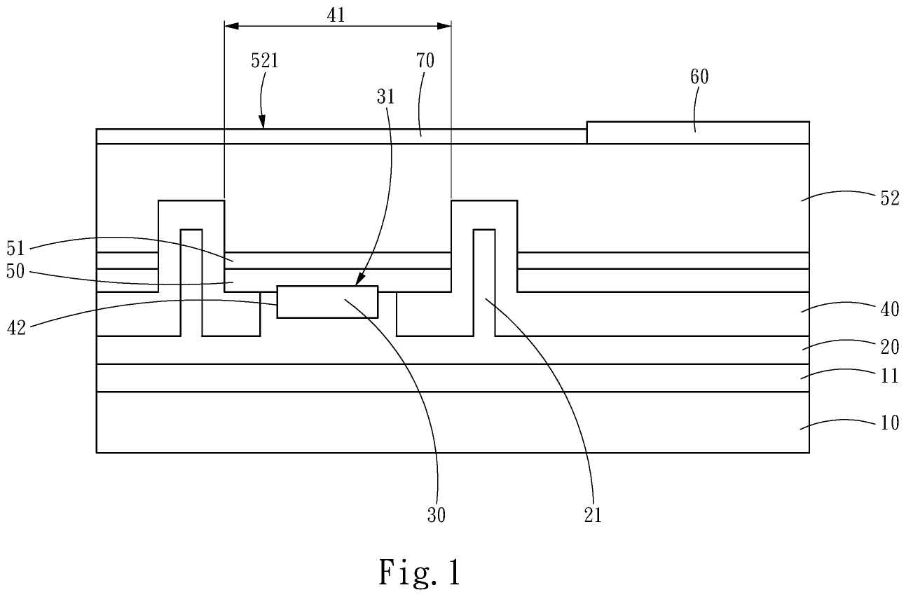

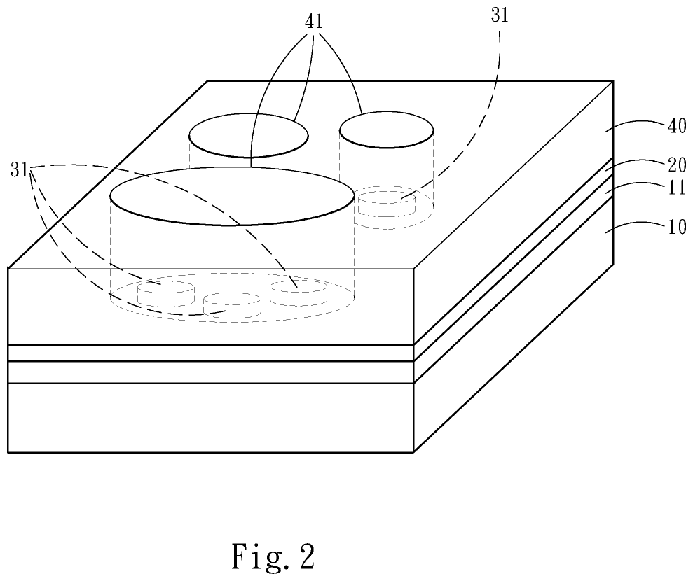

Referring to FIG. 1 and FIG. 2, the invention provides a surface light emitting element with high heat dissipation and uniform light emission, comprising a thermally-conductive and electricity-conductive substrate 10, a metal adhesive layer 11, a metal reflective layer 20, a first metal conductive layer 30, an omnidirectional reflecting current isolation layer 40, a first-type semiconductor current spreading layer 50, a light emitting diode layer 51, a second-type semiconductor current spreading layer 52, a second metal conductive layer 60 and an anti-reflection layer 70. The metal adhesive layer 11 is arranged on the thermally-conductive and electricity-conductive substrate 10 and may be made of Indium (In) or Titanium and Gold bilayer (Ti/Au). The thermally-conductive and electricity-conductive substrate 10 is selected as a copper substrate.

The metal reflective layer 20 is arranged on the metal adhesive layer 11 and includes at least one surrounding wall structure 21 which is vertically arranged and in a surrounding shape. The omnidirectional reflecting current isolation layer 40 is arranged on the metal reflective layer 20 and entirely covers the two faces of the at least one surrounding wall structure 21 to form at least on cylindrical channel 41. Under each of the at least one cylindrical channel 41, the omnidirectional reflecting current isolation layer 40 is formed with at least one channel opening 42 exposing the metal reflective layer 20. Preferably, the omnidirectional reflecting current isolation layer 40 has a thickness in a range from 1000 angstroms to 15000 angstroms (Å).

A shape of the at least one cylindrical channel 41 is selected from a group consisting of circle, rectangle, square and polygon. In order to form a total reflection interface between the omnidirectional reflecting current isolation layer 40 and the metal reflective layer 20, the omnidirectional reflecting current isolation layer 40 may be made of a material with a large refractive index, such as metallic oxides, metal nitrides and metal fluorides including silicon oxide, titanium oxide, aluminum oxide, titanium nitride, silicon nitride and magnesium fluoride; and the metal reflective layer 20 is made of a material with a small refractive index, such as silver, aluminum, titanium, gold, aluminum-silver and silver-lead.

The first metal conductive layer 30 is arranged on the metal reflective layer 20 and forms at least one circular platform 31 in each of the at least one channel opening 42. In one implementation, the circular platform 31 further extends into the cylindrical channel 41. As shown in FIG. 2, one of the at least one cylindrical channel 41 can be provided with one circular platform 31, and another one of the at least one cylindrical channel can be provided with a plurality of circular platforms 31. The circular platform 31 has a height in a range from 1000 angstroms (Å) to 4000 angstroms (Å). The circular platform 31 has a diameter in a range from 5 microns (jam) to 10 microns (jam). In one embodiment, a plurality of circular platforms 31 are provided in one of the at least one cylindrical channel 41, and a distance between two of the at least one circular platforms 31 is in a range from 20 microns to 100 microns.

The first-type semiconductor current spreading layer 50 is arranged on the first metal conductive layer 30 and the omnidirectional reflecting current isolation layer 40. The first-type semiconductor current spreading layer 50 is located in the at least one cylindrical channel 41. The light emitting diode layer 51 is arranged on the first-type semiconductor current spreading layer 50 and located in the at least one cylindrical channel 41. In one embodiment, in addition to being located in the at least one cylindrical channel 41, the first-type semiconductor current spreading layer 50 and the light emitting diode layer 51 are also provided outside the at least one cylindrical channel (as shown in FIG. 1). In another embodiment, the first-type semiconductor current spreading layer 50 and the light emitting diode layer 51 only exist in the at least one cylindrical channel 41. The second-type semiconductor current spreading layer 52 is arranged on the light emitting diode layer 51. The second-type semiconductor current spreading layer 52 fully fills the at least one cylindrical channel 41 and covers the omnidirectional reflecting current isolation layer 40.

The second-type semiconductor current spreading layer 52 is made of a material selected from a group consisting of AlₓGa₁₋ₓAs/Al_{y}Ga_{1-y}As and AlₓGa_{y}In_{1-x-y}P/AlₛInₜP. The second-type semiconductor current spreading layer 52 allows light of a specific wavelength interval to pass through.

The second metal conductive layer 60 is arranged on the second-type semiconductor current spreading layer 52 and is arranged away from the at least one cylindrical channel 41. The second-type semiconductor current spreading layer 52 is provided with at least one light exit opening 521 aligning to the at least one cylindrical channel 41. The anti-reflection layer 70 is arranged on the second-type semiconductor current spreading layer 52 and is located in the at least one light exit opening 521.

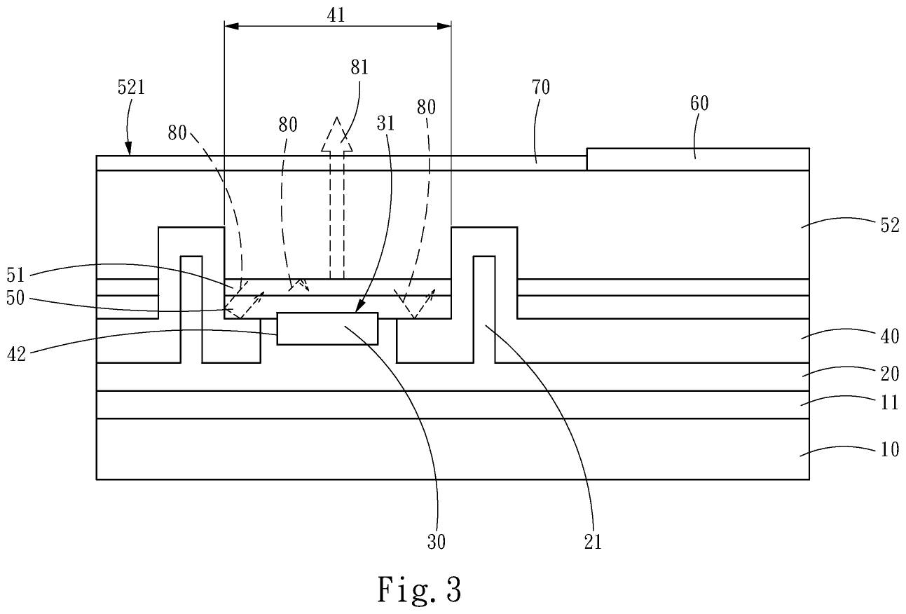

Referring to FIG. 3, when a forward bias is formed between the first metal conductive layer 30 and the second metal conductive layer 60, the light emitting diode layer 51 is excited to produce light 80, 81. After being produced by the light emitting diode layer 51, the light 80, 81 are emitted in all directions, wherein the light 80 which does not face the light exit opening 521 is reflected by the metal reflective layer 20, the first metal conductive layer 30 and the omnidirectional reflecting current isolation layer 40, The second-type semiconductor current spreading layer 52 only allows the light 81 of a specific wavelength interval to pass through. Therefore, in the light 80, 81 being emitted to the second-type semiconductor current spreading layer 52, the light 80 is reflected by the second-type semiconductor current spreading layer 52 to be transmitted toward the light emitting diode layer 51 and then resonants with the light emitting diode layer 51 for excitation to produce the light 80, 81 again. Therefore, only the light 81 of the specific wavelength interval passes through the second-type semiconductor current spreading layer 52 and is emitted outside from the light exit opening 521. Thus, amount of light emission is increased, so that the demand for high brightness is met.

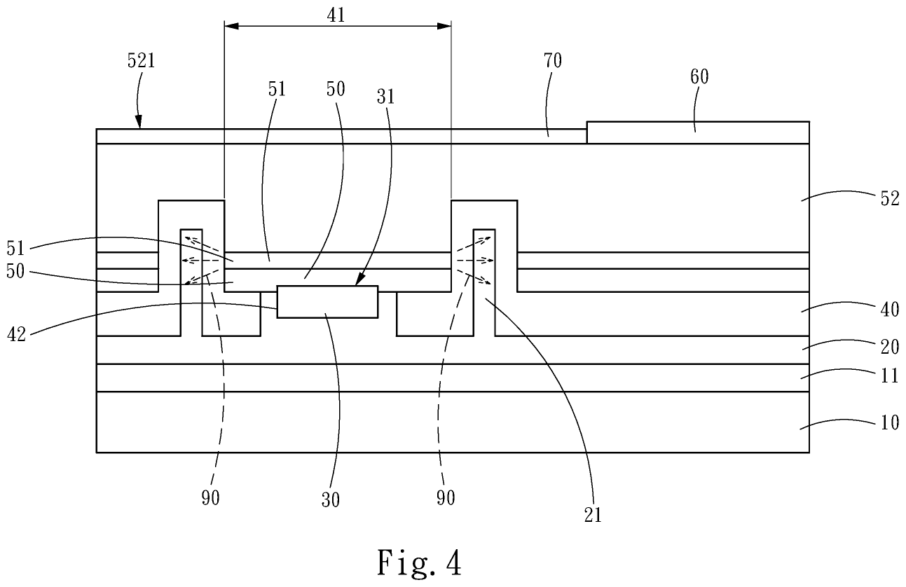

Referring to FIG. 4, when the light emitting diode layer 51 produces the heat due to light emission, the surrounding wall structure 21 of the metal reflective layer 20 is located on the side edge of the light emitting diode layer 51 and is vertically arranged. Therefore, the heat produced by the light emitting diode layer 51 has multiple heat dissipation paths 90, and lengths of the multiple heat dissipation paths 90 do not have significant difference. The problem that the heat focuses on one of the multiple heat dissipation paths 90 is avoided. That is to say, the heat transfer paths of the light emitting diode layer 51 and the surrounding wall structure 21 are dispersed. Concentrated heat is avoided and the thermal conduction efficiency is increased.

Therefore, the invention at least has the advantages that:

1. In the invention, the at least one cylindrical channel limits the current to pass through the light emitting diode layer. The omnidirectional reflecting current isolation layer is arranged on the metal reflective layer so as to form an omnidirectional reflecting interface. As the omnidirectional reflecting current isolation layer covers the surrounding wall structure, compared with the conventional technology (U.S. Pat. Nos. 7,109,527 and 7,547,921), the omnidirectional reflecting current isolation layer provides a narrower barrier region with enough space for light diffuse that effectively uniforms light emission.

2. The surrounding wall structure of the metal reflective layer is located on the side of the light emitting diode layer and is vertically arranged. Light emitting area sacrificed to provide the surrounding wall structure is smaller than that of an oblique side wall structure. Therefore, more surrounding wall structures may be arranged for assisting heat dissipation while obtaining the same light emitting surface. Therefore, the heat transfer paths of the light emitting diode layer and the surrounding wall structure are relatively dispersed. The heat dissipation efficiency is improved due to avoiding concentrated heat, and the heat produced by the light emitting diode layer is rapidly conducted away.

What is claimed is:

1. A surface light emitting element with high heat dissipation and uniform light emission, comprising:
a thermally-conductive and electricity-conductive substrate;
a metal adhesive layer, arranged on the thermally-conductive and electricity-conductive substrate;
a metal reflective layer, arranged on the metal adhesive layer and comprising at least one surrounding wall structure, the at least one surrounding wall structure vertically arranged and in a surrounding shape;
an omnidirectional reflecting current isolation layer, arranged on the metal reflective layer and entirely covering two faces of the at least one surrounding wall structure to form at least one cylindrical channel, wherein under each of the at least one cylindrical channel, the omnidirectional reflecting current isolation layer is formed with at least one channel opening exposing the metal reflective layer;
a first metal conductive layer, arranged on the metal reflective layer and formed at least one circular platform in each of the at least one channel opening;
a first-type semiconductor current spreading layer, arranged on the first metal conductive layer and the omnidirectional reflecting current isolation layer, and the first-type semiconductor current spreading layer located in the at least one cylindrical channel;
a light emitting diode layer, arranged on the first-type semiconductor current spreading layer and located in the at least one cylindrical channel;
a second-type semiconductor current spreading layer, arranged on the light emitting diode layer, fully filling the at least one cylindrical channel and covering the omnidirectional reflecting current isolation layer;
a second metal conductive layer, arranged on the second-type semiconductor current spreading layer and arranged away from the at least one cylindrical channel, wherein the second-type semiconductor current spreading layer is provided with at least one light exit opening aligning to the at least one cylindrical channel; and
an anti-reflection layer, arranged on the second-type semiconductor current spreading layer and located in the at least one light exit opening.

2. The surface light emitting element according to claim 1, wherein the at least one circular platform further extends into the cylindrical channel.

3. The surface light emitting element according to claim 1, wherein the circular platform has a height in a range from 1000 angstroms (Å) to 4000 angstroms (Å).

4. The surface light emitting element according to claim 1, wherein the circular platform has a diameter in a range from 5 microns to 10 microns.

5. The surface light emitting element according to claim 4, wherein a plurality of circular platforms are provided in one of the at least one cylindrical channel, and a distance between two of the plurality of circular platforms is in a range from 20 microns to 100 microns.

6. The surface light emitting element according to claim 1, wherein a shape of the at least one cylindrical channel is selected from a group consisting of circle, rectangle, square and polygon.

7. The surface light emitting element according to claim 1, wherein the omnidirectional reflecting current isolation layer has a thickness in a range from 1000 angstroms to 15000 angstroms.

8. The surface light emitting element according to claim 1, wherein the second-type semiconductor current spreading layer is made of a material selected from a group consisting of AlₓGa₁₋ₓAs/Al_{y}Ga_{1-y}As and AlₓGa_{y}In_{1-x-y}P/AlₛInₜP.
